(19) United States
(12) Patent Application Publication
(10) Pub. No.: US 2025/0191983 A1
(43) Pub. Date: Jun. 12, 2025

(54) ELECTRONIC COMPONENT PACKAGE

(71) Applicant: SAMSUNG ELECTRONICS CO., LTD., SUWON-SI (KR)

(72) Inventors: IN-JAE LEE, Suwon-si (KR); DONGOK KWAK, Suwon-si (KR)

(21) Appl. No.: 18/734,610

(22) Filed: Jun. 5, 2024

(30) Foreign Application Priority Data
Dec. 8, 2023 (KR) 10-2023-0177799

(51) Int. Cl. H01L 23/13; H01L 23/00; H01L 23/498; H01L 23/522; H01L 25/16

(52) U.S. Cl. CPC H01L 23/13; H01L 23/49822; H01L 23/5223; H01L 23/562; H01L 24/16; H01L 24/32; H01L 24/73; H01L 25/16; H01L 24/48; H01L 2224/16225; H01L 2224/32225; H01L 2224/48227; H01L 2224/73204; H01L 2924/1815

(57) ABSTRACT

Provided is an electronic component package including a substrate including an insulating layer, a wiring layer including a first connection pad and a second connection pad, a protection layer disposed on the insulating layer and having an opening exposing at least a portion of each of the first connection pad and the second connection pad, and at least one protruded structure disposed on the protection layer; an electronic component disposed on the substrate and including a first electrode electrically connected to the first connection pad and a second electrode electrically connected to the second connection pad; and a molding material disposed on the substrate to mold the electronic component; wherein the protruded structures include a first protruded structure supporting the first electrode and a second protruded structure supporting the second electrode.

### CROSS-REFERENCE TO RELATED APPLICATION

This application claims priority to and the benefit of Korean Patent Application No. 10-2023-0177799 filed in the Korean Intellectual Property Office on Dec. 8, 2023, the entire contents of which are incorporated by reference herein.

### BACKGROUND

### (a) Field of the Disclosure

The present disclosure generally relates to an electronic component package. More particularly, the present disclosure relates to an electronic component package with a sufficient gap between the electron element and the substrate to be filled with molding material to prevent electric short defects.

### (b) Description of the Related Art

Many approaches are being investigated to thin out the packages that house the semiconductor chips and passive components used in electronic devices, as these devices get smaller and thinner. The ability to reduce the substrate's thickness by the wire pattern's thickness is one advantage of embedded trace substrate (ETS) technology, which inserts wire patterns into the substrate's insulating layer surface to create electronic component packages.

When mounting an electron device such as a multilayer ceramic capacitor (MLCC) on this ETS substrate to improve the performance of the electronic component package, since a space between the substrate and the electron element is not sufficient, there may be a problem in which it is difficult to sufficiently fill the space between them with an epoxy molding compound (EMC).

An electric short that connects adjacent terminals to one another may occur in the empty space created when the EMC is not filled between the electron device and the substrate. This occurs when the solder paste used to mount the electron device melts and flows during the reflow process for mounting the electronic component package. Additionally, air and moisture present in the empty space may deteriorate the reliability of the electronic component package in a high temperature and humid environment.

### SUMMARY

In one aspect, the present disclosure provides an electronic component package with a sufficient gap between the electron element and the substrate to be filled with molding material.

In another aspect, the present disclosure provides an electronic component package that can prevent electric short defects.

In another aspect, the present disclosure seeks to provide an electronic component package that can improve a reliability deterioration.

The present disclosure as an embodiment provides an electronic component package including a substrate including an insulating layer, a wiring layer including a first connection pad and a second connection pad, a protection layer disposed on the insulating layer, and at least one protruded structure disposed on the protection layer, wherein an opening exposing at least a portion of each of the first connection pad and the second connection pad is defined in the protection layer; an electronic component disposed on the substrate, wherein the electronic component includes a first electrode electrically connected to the first connection pad and a second electrode electrically connected to the second connection pad; and a molding material disposed on the substrate to mold the electronic component, wherein the protruded structure includes a first protruded structure supporting the first electrode and a second protruded structure supporting the second electrode.

The present disclosure as another embodiment provides an electronic component package including a substrate including an insulating layer, a wiring layer including a connection pad, a protection layer disposed on the insulating layer, and at least one protruded structure disposed on the protection layer, wherein the opening is defined in the protection layer and the protruded structure is adjacent to the opening; an electronic component placed on the substrate and electrically connected to the connection pad; and a molding material disposed on the substrate to mold the electronic component and including a resin and a filler, wherein an opening exposes at least part of the connection pad and the insulating layer adjacent thereto, the electronic component includes a region disposed on the protruded structure and a region disposed on the opening, and a gap between the region placed on the opening of the electronic component and the substrate is larger than an average particle diameter of the filler.

The present disclosure as another embodiment provides an electronic component package including a substrate including an insulating layer, a wiring layer including a first connection pad and a second connection pad, a protection layer disposed on the insulating layer, and at least one protruded structure disposed on the protection layer, wherein an opening exposing at least a portion of each of the first connection pad and the second connection pad is defined in the protection layer; an electronic component placed on the substrate and electrically connected to the first connection pad; a semiconductor chip placed on the substrate, wherein the semiconductor is spaced apart from the electronic component, and electrically connected to the second connection pad; a plurality of conductive bumps electrically connecting the semiconductor chip to the second connection pad; an underfill resin interposed between the semiconductor chip and the substrate and covering the conductive bumps; and a molding material placed on the substrate to mold the electronic component and the semiconductor chip, wherein the protruded structures include a first protruded structure, a second protruded structure, and a third protruded structure, the first protruded structure and the second protruded structure support the electronic component, and the third protruded structure blocks at least one side of the semiconductor chip on a plane.

According to one aspect of the present disclosure, the electronic component package may be provided having the sufficient gap between the electronic component and the substrate to be filled with a molding material.

According to another aspect of the present disclosure, the electronic component package that may prevent electric short defects can be provided.

According to another aspect of the present disclosure, the electronic component package that may improve a reliability deterioration may be provided.

### BRIEF DESCRIPTION OF THE DRAWINGS

FIG. 1 is a cross-sectional view of an electronic component package according to an embodiment of the present disclosure.

FIG. 2 and FIG. 3 are enlarged cross-sectional views of a region A1 of FIG. 1 according to an embodiment of the present disclosure.

FIG. 4 is an enlarged top plan view of a region A1 of FIG. 1 according to an embodiment of the present disclosure.

FIG. 5 and FIG. 6 are top plan view views of a region A1 of FIG. 4 according to an embodiment of the present disclosure.

FIG. 7 is a cross-sectional view of an electronic component package according to another embodiment of the present disclosure.

FIG. 8 is an enlarged cross-sectional view of a region A2 of FIG. 7 according to another embodiment of the present disclosure.

FIG. 9 is a cross-sectional view of an electronic component package according to another embodiment of the present disclosure.

FIG. 10 is an enlarged cross-sectional view of a region A3 of FIG. 9 according to another embodiment of the present disclosure.

FIG. 11 is a cross-sectional view of an electronic component package according to another embodiment of the present disclosure.

FIG. 12 is a cross-sectional view of an electronic component package according to another embodiment of the present disclosure.

### DETAILED DESCRIPTION

The present disclosure will be described more fully hereinafter with reference to the accompanying drawings, in which exemplary embodiments of the disclosure are shown. As those skilled in the art would realize, the described embodiments may be modified in various different ways, all without departing from the spirit or scope of the present disclosure.

In order to clearly explain the present disclosure, portions that are not directly related to the present disclosure are omitted, and the same reference numerals are attached to the same or similar constituent elements through the entire specification.

In addition, the size and thickness of each configuration shown in the drawings are arbitrarily shown for better understanding and ease of description, but the present disclosure is not limited thereto. In the drawings, the thickness of layers, films, panels, regions, etc., are exaggerated for clarity. In the drawings, for better understanding and ease of description, the thicknesses of some layers and areas are exaggerated.

Throughout this specification and the claims that follow, when it is described that an element is “coupled” to another element, the element may be “directly coupled” to the other element or “indirectly coupled” to the other element through a third element.

In a similar sense, this includes being “physically connected” as well as being “electrically connected”. In addition, unless explicitly described to the contrary, the word “comprise”, and variations such as “comprises” or “comprising”, will be understood to imply the inclusion of stated elements but not the exclusion of any other elements.

In addition, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, in the specification, the phrase “on a plane” means viewing the object portion from the top, and the phrase “on a cross-section” means viewing a cross-section of which the object portion is vertically cut from the side.

Additionally, throughout the specification, sequential numbers such as first and second are used to distinguish a component from other components that are the same or similar to it, and are not necessarily intended to refer to a specific component. Accordingly, a component referred to as a first component in a specific part of this specification may also be referred to as a second component in other parts of this specification.

Additionally, throughout the specification, references to any component in a singular include references to a plurality of these components, unless specifically stated to the contrary. For example, “an insulating layer” may be used to mean not only one insulating layer, but also a plurality of insulating layers, such as two, three or more.

Additionally, throughout the specification, references to one side and the other side are intended to distinguish between different sides, and are not necessarily intended to limit it to a specific side. Accordingly, a side referred to as one side in a particular part of this specification may be referred to as the other side in other parts of this specification.

Hereinafter, electronic component packages according to embodiments of the present disclosure will be described with reference to accompanying drawings.

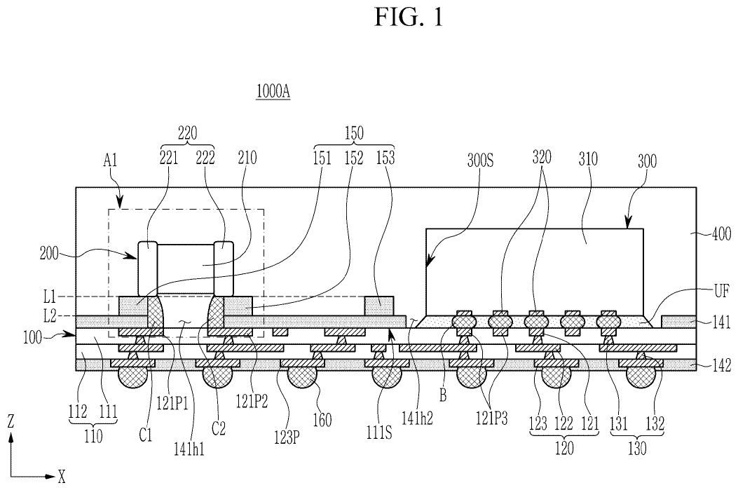

FIG. 1 is a cross-sectional view of an electronic component package according to an embodiment of the present disclosure.

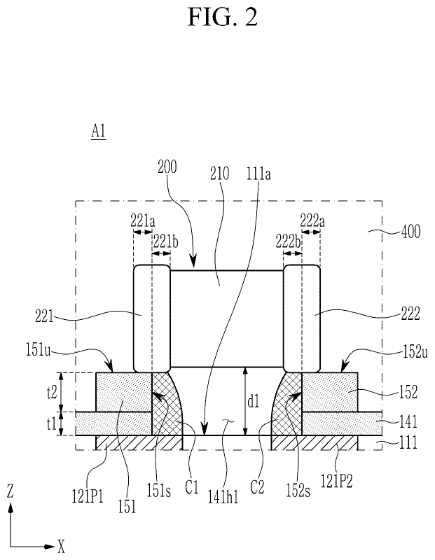

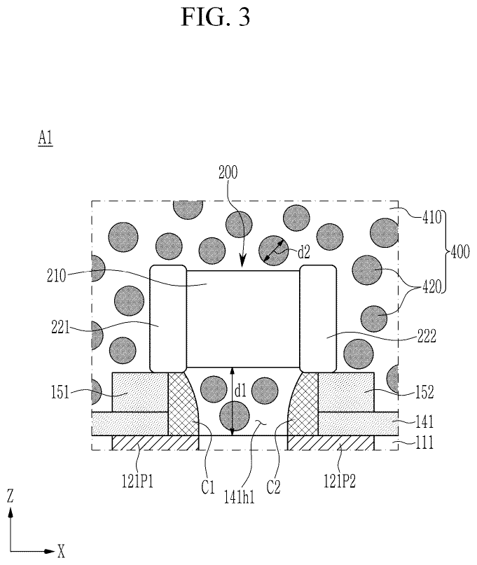

FIG. 2 and FIG. 3 are enlarged cross-sectional views of a region A1 of FIG. 1 according to an embodiment of the present disclosure.

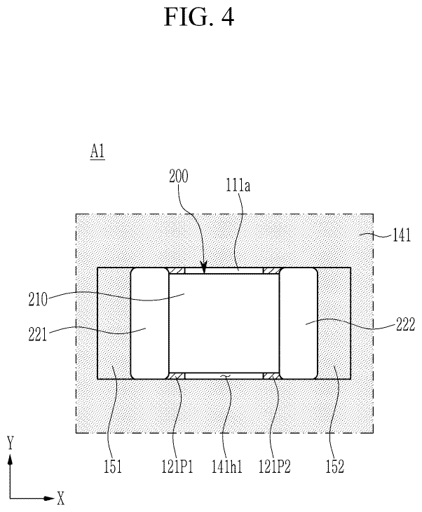

FIG. 4 is an enlarged top plan view of a region A1 of FIG. 1 according to an embodiment of the present disclosure.

In FIG. 4, only some components are shown to clearly indicate an arrangement relationship between explained components, and other components are omitted.

Referring to FIG. 1, an electronic component package 1000A includes a substrate 100, an electronic component 200, a semiconductor chip 300, and a molding material 400.

The substrate 100 may include a plurality of insulating layers 110, a plurality of wiring layers 120, a plurality of vias 130, protection layers 141 and 142, at least one protruded structure 150, and a plurality of conductive bumps 160.

In this case, the substrate 100 may include a first wiring layer 121, a first insulating layer 111 covering the first wiring layer 121, a second wiring layer 122 disposed on the first insulating layer 111, a first via 131 penetrating the first insulating layer 111 to connect the second wiring layer 122 and the first wiring layer 121, a second insulating layer 112 disposed on the first insulating layer 111 to cover the second wiring layer 122, a third wiring layer 123 disposed on the second insulating layer 112, a second via 132 penetrating the second insulating layer 112 to connect the third wiring layer 123 and the second wiring layer 122.

The protection layer may include a first protection layer 141 and a second protection layer 142. For example, the first protection layer 141 may be disposed on the first insulating layer 111 and the second protection layer 142 may be disposed on the second insulating layer 112, and the protruded structure 150 may be disposed on the first protection layer 141. Additionally, the conductive bump 160 may be disposed on the second protection layer 142 and a connection pad 123P included in the third wiring layer 123.

The insulating layer 110 may insulate wiring layers 120 arranged in different layers from each other. For example, the first insulating layer 111 may be interposed between the first wiring layer 121 and the second wiring layer 122, and the second insulating layer 112 may be interposed between the second wiring layer 122 and the third wiring layer 123. An insulating material may be used as a material for the first and second insulating layers 111, 112, and for example prepreg (e.g., pre-impregnated material) may be used.

The wiring layer 120 may perform various roles depending on a design, and may include a signal pattern, a power pattern, or a ground pattern, etc.

The first wiring layer 121 may include a first connection pad 121P1, a second connection pad 121P2, and a third connection pads 121P3 that are electrically connected to the electronic component 200 or the semiconductor chip 300. For example, the first connection pad 121P1 and the second connection pad 121P2 may electrically be connected to the electronic component 200, and the third connection pads 121P3 may electrically be connected to the semiconductor chip 300.

The substrate 100 may have an embedded trace substrate (ETS) structure, and the first wiring layer 121 including the first, second, and third connection pads 121P1, 121P2, and 121P3 may be embedded in the first insulating layer 111 and be exposed to a bottom surface 111S of the first protection layer 141 facing the electronic component 200 of the first insulating layer 111.

The third wiring layer 123 may include fourth connection pads 123P that are electrically connected to the conductive bumps 160.

Conductive materials may be used as materials for the wiring layer 120. For example aluminum (Al), copper (Cu), gold (Au), silver (Ag), platinum (Pt), tin (Sn), chromium (Cr), Palladium (Pd), lead (Pb), titanium (Ti), or their alloys may be used for the wiring layer 120.

Additionally, the number of wiring layers 120 is not particularly limited and may be more or less than what is shown in the drawing. For example, in this case, first, second, and third wiring layers 121, 122, 123 may be used. However, in another example, the number of wiring layers 120 may be less than or more than three.

The via 130 including the first via 131 and the second via 132 may electrically connect each of the wiring layers 120 positioned in different layers to each other. For example, the first via 131 may be interposed between the first wiring layer 121 and the second wiring layer 122, and the second via 132 may be interposed between the second wiring layer 122 and the third wiring layer 123.

The via 130 may have a tapered shape, a cylinder shape, etc. where a diameter narrows in a direction from one surface to the other surface. For example, the first via 131 may have a tapered shape whose diameter narrows in the direction from the second insulating layer 112 to the first insulating layer 111. In this case, the diameter of the bottom surface of the first via 131 may be greater than the diameter of the upper surface of the first via 131.

The same material as the wiring layer 120 may be used for the via 130. Additionally, each of the vias 130 is integrally formed with each of the wiring layers 120 and may not have a boundary with the wiring layer 120. For example, the first via 131 may be integrally formed with the second wiring layer 122, and the second via 132 may be integrally formed with the third wiring layer 123.

The first protection layer 141 may be disposed on the first insulating layer 111. An opening 141h1 that exposes at least a portion of each of the first connection pad 121P1 and the second connection pad 121P2 may be defined in the first protection layer 141. Depending on the design, the opening 141h1 of the first protection layer 141 may further expose the region adjacent to the first connection pad 121P1 and/or the second connection pad 121P2 of the first insulating layer 111. For example, as shown in FIG. 2, the opening 141h1 of the first protection layer 141 may further expose a region 111a interposed between the first connection pad 121P1 and the second connection pad 121P2 of the first insulating layer 111.

Additionally, an opening 141h2 that exposes the third connection pad 121P3 may be further defined in the first protection layer 141. Depending on the design, the opening 141h2, which exposes the third connection pad 121P3, may further expose the region interposed between the third connection pads 121P3 of the first insulating layer 111.

The second protection layer 142 may be disposed on the second insulating layer 112, and an opening that exposes at least a portion of each fourth connection pad 123P may be defined in the second protection layer 142.

The first protection layer 141 and the second protection layer 142 may include an insulating material, for example a solder resist.

The plurality of conductive bumps 160 may electrically connect the electronic component package 1000A to other components that are distinct from the electronic component package 1000A, such as a main substrate and an interposer substrate. Each of the conductive bumps 160 may fill the openings of the second protection layer 142 and be electrically connected to the fourth connection pads 123P. The conductive bumps 160 may be a solder ball for example.

The protruded structure 150 may be disposed on the first protection layer 141. The protruded structure 150 is placed only on some portions of the first protection layer 141.

In this case, the protruded structure 150 may include a first protruded structure 151 and a second protruded structure 152. Both of the first protruded structure 151 and the second protruded structure 152 may be interposed between the first protection layer 141 and the electronic component 200 so that the first protruded structure 151 and the second protruded structure 152 may support the electronic component 200. In an embodiment, more particularly, the first protruded structure 151 may support the first electrode 221 of the electronic component 200 and the second protruded structure 152 may support the second electrode 222 of the electronic component 200.

Referring to FIG. 2, some portions 221b and 222b of the first electrode 221 and the second electrode 222 of the electronic component 200 are positioned in the opening 141h1 of the first protection layer 141. In this case, the first protruded structure 151 and the second protruded structure 152 may be spaced apart from each other with respect to the opening 141h1 of the first protection layer 141 and may support some other regions 221a and 221b of the first electrode 221 and the second electrode 222, respectively. The opening 141h1 of the first protection layer 141 may be disposed in the space between the first protruded structure 151 and the second protruded structure 152 on a plane.

The first protruded structure 151 and the second protruded structure 152 may be arranged to extend outside of the electronic component 200 in the direction X. Furthermore, the widths of the first protruded structure 151 and the second protruded structure 152 may be wider than the widths of the first electrode 221 and the second electrode 222 in the direction X. In FIG. 4, the first protruded structure 151 and the second protruded structure 152 are shown as having the same length in the direction Y for the first electrode 221 and the first connection pad 121P1, and for the second electrode 222 and the second connection pad 121P2. However, this is only an example, and in another example, the length of each of first protruded structure 151, the second protruded structure 152, the first electrode 221, the second electrode 222, the first connection pad 121P1, and the second connection pad 121P2 in the direction Y may vary depending on the design.

The protruded structure 150 may further include a third protruded structure 153 that blocks at least one side 300S of the semiconductor chip 300 in plan. For example, the third protruded structure 153 may be interposed between the electronic component 200 and the semiconductor chip 300 and may block one side 300S of the semiconductor chip 300. Depending on the design, the third protruded structure 153 may block two or more sides 300S of the semiconductor chip 300. The third protruded structure 153 may prevent problems such as a underfill resin UF that fills the space between the semiconductor chip 300 and the substrate 100 bleeds to the outside of the substrate 100, contaminating the product, and deteriorating the reliability.

Since the first protruded structure 151, the second protruded structure 152, and the third protruded structure 153 may be formed through the same process, the first protruded structure 151, the second protruded structure 152, and the third protruded structure 153 may include the same material. Additionally, the first protruded structure 151, the second protruded structure 152, and the third protruded structure 153 may be disposed on the first protection layer 141 and may have the same thickness. Therefore, the level L1 at which a top surface of each of the first protruded structure 151, the second protruded structure 152, and the third protruded structure 153 is positioned, and the level L2 at which a bottom surface of each of the first protruded structure 151, the second protruded structure 152, and the third protruded structure 153 is positioned, may substantially be equal to each other.

The protruded structure 150 may include the same material as the first protection layer 141. If the protruded structure 150 is formed of the same material as the first protection layer 141, the junction strength between the protruded structure 150 and the first protection layer 141 may be improved. As described above, the first protection layer 141 may include an insulating material, and the protruded structure 150 may also include an insulating material. The protruded structure 150 may include a solder resist like the first protection layer 141. When using a conductive material as the first protection layer 141, it may not be advisable because the first protection layer 141 may melt together during the solder reflow process to form the first connection structure C1 and the second connection structure C2.

The thickness t2 which is a thickness of the first protruded structure 151 in the direction Z (or a thickness of the second protruded structure 152 in the direction Z) may be thicker than the thickness t1 which is a thickness of the first protection layer 141 in the direction Z in the direction Z. For example, the thickness t1 of the first protection layer 141 may be around 6 μm to 14 μm, and the thickness t2 of the protruded structure 150 may be around 40 μm or more. In one embodiment, a sufficient gap between the electronic component 200 and the substrate 100 may be secured by adjusting the thickness of the protruded structure 150 disposed on the first protection layer 141.

The electronic component 200 may be placed on the substrate 100 and be electrically connected to the wiring layer 120 through the first connection pad 121P1 and the second connection pad 121P2.

The electronic component 200 may include a body 210, a first electrode 221 electrically connected to the first connection pad 121P1, and a second electrode 222 electrically connected to the second connection pad 121P2. The body 210 may be interposed between the first electrode 221 and the second electrode 222.

The electronic component 200 may be a passive device, such as a multi-layer ceramic capacitor (MLCC), in this case, the body 210 may include a dielectric material such as ceramic and internal electrodes positioned in the dielectric material and connected to the first electrode 221 or the second electrode 222. In a technical field to which the present disclosure belongs, the first electrode 221 and the second electrode 222 may each be referred to as an external electrode.

The electronic component package 1000A may further include a first connection structure C1 and a second connection structure C2 for electrically connecting the electronic component 200 and the substrate 100. The first connection structure C1 may be placed between the first electrode 221 and the first connection pad 121P1 to electrically connect the first electrode 221 and the first connection pad 121P1, and the second connection structure C2 may be placed between the second electrode 222 and the second connection pad 121P2 to electrically connect the second electrode 222 and the second connection pad 121P2. The first connection structure C1 may cover the side of the first protection layer 141 and the side 151s of the first protruded structure 151, and the second connection structure C2 may cover the side of the first protection layer 141 and the side 152s of the second protruded structure 152. The first connection structure C1 and the second connection structure C2 may be a solder paste, for example.

The first connection structure C1 and the second connection structure C2 may be spaced apart from each other. For example, the first connection structure C1 and the second connection structure C2 may be disposed inside of the opening 141h of the first protection layer 141. Furthermore, the first connection structure C1 and the second connection structure C2 may be interposed between the first protruded structure 151 and the second protruded structure 152 to prevent an electric short between electrodes, and the molding material 400 may fill the space between the first connection structure C1 and the second connection structure C2 of the opening 141h.

Referring to FIG. 2, the electronic component 200 includes a region disposed on the protruded structures 151 and 152 and a region disposed on the opening 141h1 of the first protection layer 141. The electronic component 200 may be supported by the region disposed on the protruded structures 151 and 152, and be electrically connected to the first connection pad 121P1 and the second connection pad 121P2 through the region placed on the opening 141h1, while securing a distance d1 from the substrate 100.

In an embodiment, the regions disposed on the protruded structures 151 and 152 of the electronic component 200 may be electrodes 220 positioned at both ends of the electronic component 200 facing the direction X. For example, the electronic component 200 may be supported by the protruded structures 151 and 152 as a portion of the region 221a of the first electrode 221 is disposed on the first protruded structure 151 and a portion of the region 222a of the second electrode 222 is disposed on the second protruded structure 152. In addition, the electronic component 200 may be electrically connected to the connection pads 121P1 and 121P2 by placing another part of the region 221b of the first electrode 221 on the first connection structure C1 and another part of the region 222b of the second electrode 222 on the second connection structure C2. In this case, some portions 221a of the first electrode 221 of the electronic component 200 may be supported by the first protruded structure 151 and the first protection layer 141, and some portions 222a of the second electrode 222 of the electronic component 200 may be supported by the second protruded structure 152 and the first protection layer 141. More particularly, the other portions 221b of the first electrode 221 of the electronic component 200 may be supported by the first connection structure C1, and the other portions 222b of the second electrode 222 of the electronic component 200 may be supported by the second connection structure C2. The body 210 of the electronic component 200 may be placed on opening 141h1. However, depending on the design, the present disclosure may be conducted so that the regions of the body 210 positioned at both ends facing the direction Y of the electronic component 200 are placed on the protruded structures 151 and 152.

Referring to FIG. 2 and FIG. 3, the distance d1 which is measured from the bottom surface of the body 210 of the electronic component 200 to the region 111a of the first insulating layer 111 of the electronic component 200 may be greater than an average particle diameter D₅₀ of the filler 420 of the molding material 400. The distance d1 between the region placed on the opening 141h1 of the electronic component 200 and the region 111a of the first insulating layer 111 may mean a distance between the region disposed on the opening 141h1 of the electronic component 200 and the region 111a of the first insulating layer 111 exposed through the opening 141h1 of the protection layer 141. Additionally, the average particle diameter D₅₀ of the filler 420 refers to the particle diameter corresponding to 50% of the cumulative weight in the distribution of the particle diameter d2 of the filler 420. For example, the average particle diameter D₅₀ of the filler 420 may be 45 μm, and the distance d1 between the region placed on the opening 141h1 of the electronic component 200 and the region 111a of the first insulating layer 111 may be greater than 46 μm. According to the present disclosure, by placing the electronic component 200 on the protruded structures 151 and 152, the distance d1 between the region placed on the opening 141h1 of the electronic component 200 and the region 111a of the first insulating layer 111 may be greater than the average particle diameter D₅₀ of the filler 420 of the molding material 400 so that the molding material 400 may be efficiently filled with the space of the opening 141h.

When the substrate 100 is an ETS structure, the distance d1 between the region placed on the opening 141h1 of the electronic component 200 and the substrate 100 may also be the same as the gap between the region disposed on the opening 141h1 of the electronic component 200 and the first connection pad 121P1 or the second connection pad 121P2. Additionally, the distance d1 between the region disposed on the opening 141h1 of the electronic component 200 and the region 111a of the first insulating layer 111 may be equal to the sum of the thickness t1 of the protection layer 141 and the thickness t2 of the protruded structure 150, or may be greater than the sum of these thicknesses.

The semiconductor chip 300 spaced apart from the electronic component 200 may be electrically connected to the wiring layer 120 through the third connection pad 121P3.

The semiconductor chip 300 may include a body 310 and a plurality of connection pads 320. The connection pads 320 may be disposed on the bottom of the body 310 and electrically connected to the third connection pad 121P3. The body 310 may include a semiconductor substrate such as silicon, an internal circuit formed on the semiconductor substrate, an interlayer insulating layer, etc. Each of the connection pads 320 may be formed of a conductive material such as copper (Cu) or aluminum (Al). Additionally, the semiconductor chip 300 may be arranged in a face down type so that the surface on which each of the connection pads 320 is disposed faces the substrate 100.

The type of semiconductor chip 300 is not particularly limited and may be a logic chip, a memory chip, or an application processor (AP).

The electronic component package 1000A may further include a plurality of conductive bumps B. The conductive bumps B may be disposed on the connection pads 320 and electrically connect the semiconductor chip 300 to the third connection pad 121P3. An underfill resin UF may be disposed between the semiconductor chip 300 and the substrate 100 to cover the conductive bumps B.

Each of the conductive bumps B may be formed of a conductive material such as a solder ball, and the underfill resin UF may be formed of an epoxy resin, etc., and may include a silica filler (filler) or flux.

The molding material 400 may be placed on the substrate 100 to cover (e.g., mold) the electronic component 200 and the semiconductor chip 300.

Referring to FIG. 3, a molding material 400 may include a resin 410 and a filler 420. Resin 410 may be a thermosetting resin such as epoxy resin or a thermoplastic resin such as polyimide, and the filler 420 may include an inorganic filler such as silica (SiO₂), alumina (Al₂O₃), a glass fiber. For example, the molding material 400 may be an epoxy molding compound (EMC) including an epoxy resin and a silica filler dispersed therein.

The molding material 400 may fill at least part of the space between the electronic component 200 and the substrate 100. For example, the molding material 400 may fill at least part of the space between the region of the electronic component 200 placed in the opening 141h1 of the first protection layer 141 and the region 111a of the first insulating layer 111 exposed by the opening 141h1 of the first protection layer 141. In this case, the molding material 400 may move into the opening 141h1 through the exposed portions (e.g., gap) between the electronic component 200 and the region 111a of the first insulating layer 111. The region of the electronic component 200 disposed on the opening 141h1 of the first protection layer 141 may be the body 210, a partial region 221b of the first electrode 221, and a partial region 222b of the second electrode 222.

Meanwhile, the solder paste used when mounting the electronic component during the reflow process for mounting the electronic component package melts and flows into the empty space generated when the molding material is not filled between the electronic component and the substrate, thereby an electric short where adjacent terminals are connected to each other may occur. Additionally, air and moisture present in the empty space may deteriorate the reliability of the electronic component package in a high temperature and humid environment. This problem may become particularly severe when mounting the electronic component on the ETS substrate with wire patterns embedded in the insulating layer surface, as the gap between the substrate and the electronic component becomes shorter.

According to the present disclosure, by forming the protruded structures 151 and 152 on the first protection layer 141 and placing the electronic component 200 on the protruded structures 151 and 152, the sufficient spacing where the molding material 400 may be filled may be secured between the electronic component 200 and the substrate 100. In an embodiment, by placing the electronic component 200 on the protruded structures 151 and 152, the distance d1 between the electronic component 200 and the region 111a of the first insulating layer 111 is made larger than the average particle diameter D₅₀ of the filler 420 of the molding material 400 so that the molding material 400 may efficiently fill the space between the electronic component 200 and the region 111a of the first insulating layer 111. Accordingly, it is possible to provide the electronic component package that may prevent electric short defects and improve the reliability.

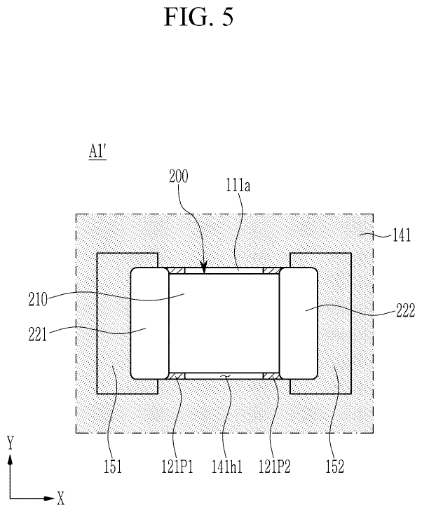

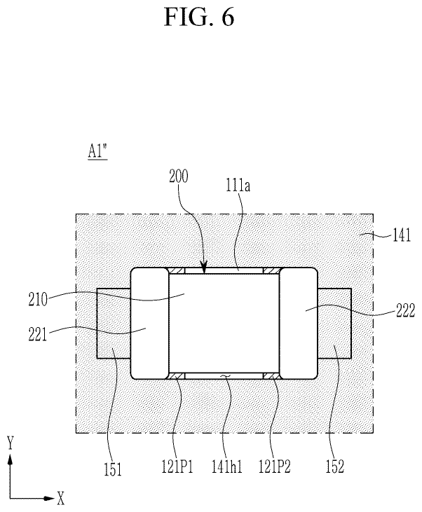

FIG. 5 and FIG. 6 are modified top plan views of a region A1 in FIG. 4 according to an embodiment of the present disclosure.

Referring to FIG. 5, to secure an align margin of the protruded structures 151 and 152 and the electronic component 200, the first protruded structure 151 has a longer structure in the direction Y than the first electrode 221, and also the second protruded structure 152 has a longer structure than the second electrode 222. In this case, the width of the first protruded structure 151 may be larger than the first electrode 221 along the direction Y. In addition, the width of the second protruded structure 152 may be larger than the second electrode 222 along the direction Y.

However, it is not limited thereof. In another example, as shown in FIG. 6, the first protruded structure 151 has a shorter structure than the first electrode 221, and the second protruded structure 152 has a shorter structure in the direction Y than the second electrode 222. In this case, unlike FIG. 5, the width of the first protruded structure 151 may be smaller than the first electrode 221 along the direction Y. In addition, the width of the second protruded structure 152 may be smaller than the second electrode 222 along the direction Y.

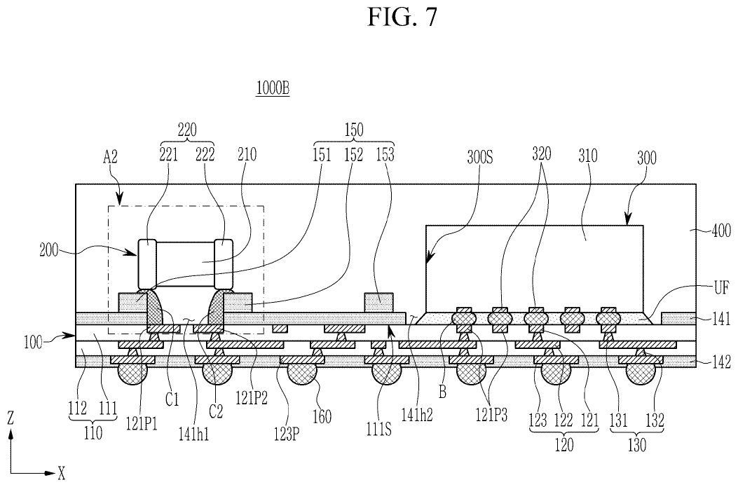

FIG. 7 is a cross-sectional view of an electronic component package according to another embodiment of the present disclosure.

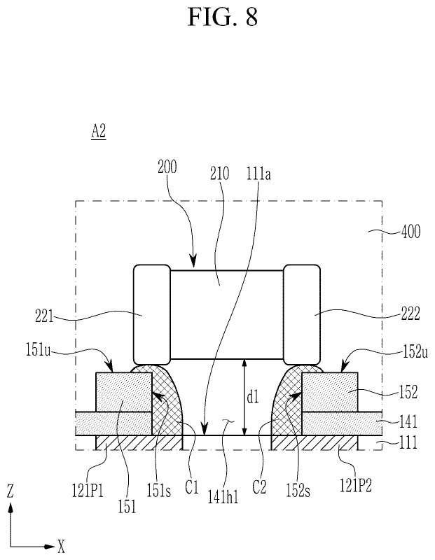

FIG. 8 is an enlarged cross-sectional view of a region A2 of FIG. 7 according to another embodiment of the present disclosure.

On an electronic component package 1000B, a first connection structure C1 may be disposed on a first protruded structure 151 so that the portion of the first connection structure C1 may be placed between the first electrode 221 of the electronic component 200 and the first protruded structure 151, and a second connection structure C2 may be disposed on a second protruded structure 152 so that the portion of the second connection structure C2 may be disposed between the second electrode 222 of the electronic component 200 and the second protruded structure 152. Thus, in this case, the electronic component 200 may be disposed on the first and second connection structures C1, C2. The electronic component package 1000B according to another embodiment may have a structure that may further increase the distance d1 between the electronic component 200 and the region 111a of the first insulating layer 111 compared to the electronic component package 1000A according to an embodiment. Thus, the distance d1 of the electronic component package 1000B may be longer than the distance d1 of the electronic component package 1000A along the direction Z.

Other than that, other contents are the same as described above in the description of the electronic component package 1000A, so detailed descriptions are omitted.

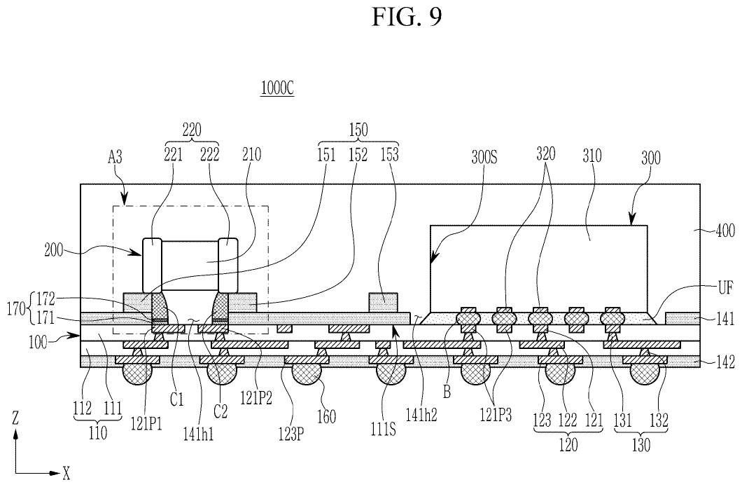

FIG. 9 is a cross-sectional view of an electronic component package according to another embodiment of the present disclosure.

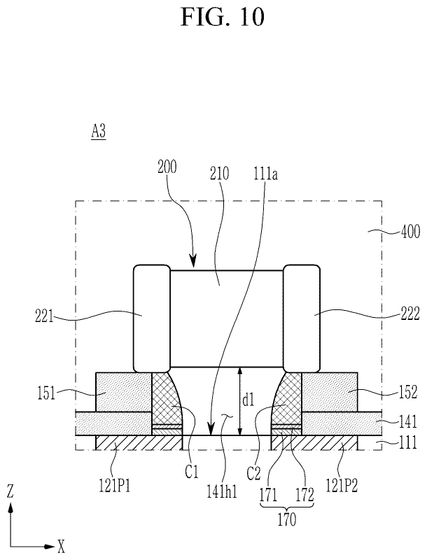

FIG. 10 is an enlarged cross-sectional view of a region A3 of FIG. 9 according to another embodiment of the present disclosure.

In an electronic component package 1000C, a substrate 100 may further include at least one conductivity layer 170 disposed respectively on regions exposed by openings of a first protection layer 141 of a first connection pad 121P1 and a second connection pad 121P2. In this case, the distance d1 from the electronic component 200 to the region 111a of the first insulating layer 111 for the electronic component package 1000C may be longer than that of the electronic component package 1000A.

For example, as shown in FIG. 10, a conductivity layer 170 includes a first conductivity layer 171 disposed on the first connection pad 121P1 and the second connection pad 121P2 The second conductivity layer 172 is disposed on the first conductivity layer 171. Each of the first and second connection structures C1, C2 is disposed on the second conductivity layer 172. The first conductivity layer 171 may be a nickel (Ni) thin film to prevent an oxidation of the connection pad and improve a junction strength between metal layers, and the second conductivity layer 172 may be a gold (Au) thin film to prevent a corrosion and an oxidation, but it is limited to thereto. For example, any material that may prevent an oxidation of the connection pad and improve a junction strength between metal layers or prevent a corrosion and an oxidation may be used.

Other than that, other contents are the same as described above in the description of the electronic component package 1000A, so detailed descriptions are omitted.

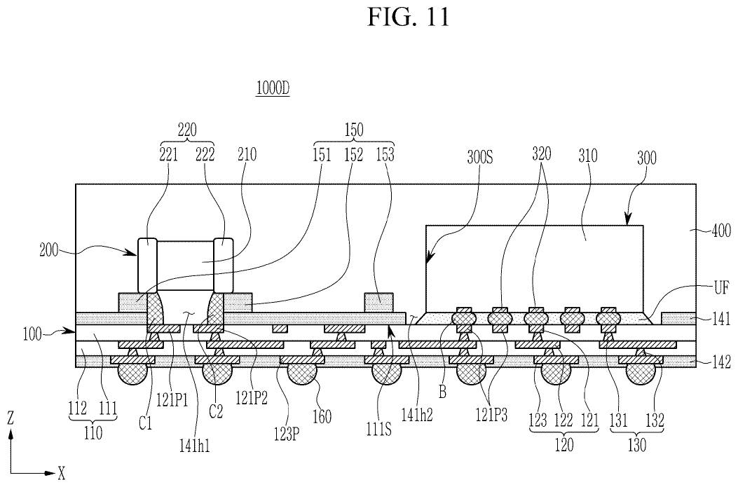

FIG. 11 is a cross-sectional view of an electronic component package according to another embodiment of the present disclosure.

In an electronic component package 1000D, an opening 141h1 of a first protection layer 141 may expose all of a first connection pad 121P1 and a second connection pad 121P2. Thus, in this case, the first connection pad 121P1 and the second connection pad 121P2 may overlap the opening 141h1 of the first protection layer 141, but may not overlap the first protection layer 141.

Other than that, other contents are the same as described above in the description of the electronic component package 1000A, so detailed descriptions are omitted.

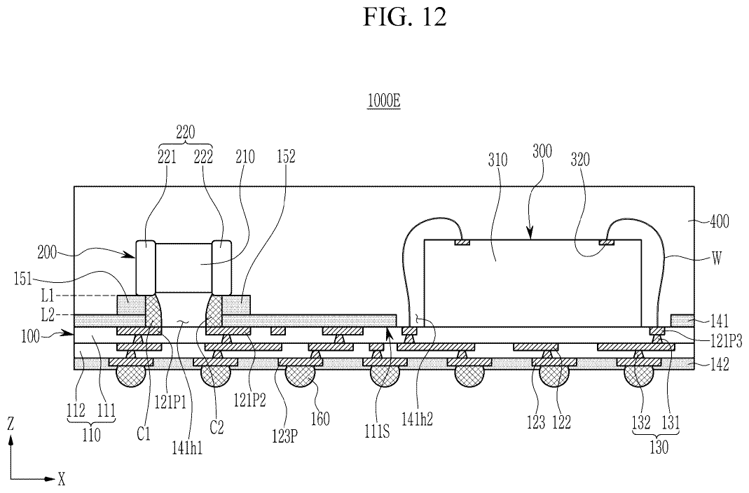

FIG. 12 is a cross-sectional view of an electronic component package according to another embodiment of the present disclosure.

In an electronic component package 1000E, the semiconductor chip 300 may be wire-bonded to a substrate 100 through a wire W. In this case, the semiconductor chip 300 may be disposed in a face up type so that the connection pad 320 may face opposite to the substrate 100, and the wire W may electrically connect the connection pad 320 to the third connection pad 121P3.

At a wire bonding, a conductive bump and an underfill resin that connect the semiconductor chip 300 and the substrate 100 may not be necessary, and a third protruded structure to prevent the bleeding of the underfill resin may also not be necessary.

Other than that, other contents are the same as described above in the description of the electronic component package 1000A, so detailed descriptions are omitted.

While this disclosure has been described in connection with what is presently considered to be practical exemplary embodiments, it is to be understood that the disclosure is not limited to the disclosed embodiments. On the contrary, it is intended to cover various modifications and equivalent arrangements included within the spirit and scope of the appended claims

What is claimed is:

1. An electronic component package comprising:
a substrate including an insulating layer, a wiring layer including a first connection pad and a second connection pad, a protection layer disposed on the insulating layer, and at least one protruded structure disposed on the protection layer, wherein an opening exposing at least a portion of each of the first connection pad and the second connection pad is defined in the protection layer;
an electronic component disposed on the substrate, wherein the electronic component includes a first electrode electrically connected to the first connection pad and a second electrode electrically connected to the second connection pad; and
a molding material disposed on the substrate to mold the electronic component,
wherein the protruded structure includes a first protruded structure supporting the first electrode and a second protruded structure supporting the second electrode.

2. The electronic component package of claim 1, wherein:
each of the first connection pad and the second connection pad is embedded in the insulating layer and exposed to an upper surface facing the electronic component of the insulating layer.

3. The electronic component package of claim 1, wherein:
the electronic component package further includes a first connection structure and a second connection structure spaced apart from each other, the first connection structure is interposed between the first electrode and the first connection pad to electrically connect the first electrode to the first connection pad, and the second connection structure is interposed between the second electrode and the second connection pad to electrically connect the second electrode and the second connection pad,
some regions of the first electrode are disposed on the first protruded structure, and other regions of the first electrode are disposed on the first connection structure, and
some regions of the second electrode are disposed on the second protruded structure, and other regions of the second electrode are disposed on the second connection structure.

4. The electronic component package of claim 3, wherein:
the electronic component further includes a body interposed between the first electrode and the second electrode, and
the molding material fills a space between the first connection structure and the second connection structure.

5. The electronic component package of claim 3, wherein:
the first connection structure extends onto a top surface of the first protruded structure so that a portion of the first connection structure is interposed between the first electrode and the first protruded structure, and
the second connection structure extends onto a top surface of the second protruded structure so that a portion of the second connection structure is interposed between the second electrode and the second protruded structure.

6. The electronic component package of claim 1, wherein:
the opening of the protection layer further exposes a region between the first connection pad and the second connection pad of the insulating layer.

7. The electronic component package of claim 6, wherein:
the molding material fills at least a part of a space between the electronic component and the region exposed by the opening of the insulating layer.

8. The electronic component package of claim 1, wherein:
the protruded structure includes equal material as the protection layer.

9. The electronic component package of claim 1, wherein:
the protection layer and the protruded structure include an insulating material.

10. The electronic component package of claim 1, wherein
the electronic component is a multi-layer ceramic capacitor (MLCC).

11. The electronic component package of claim 10, further comprising:
a semiconductor chip disposed on the substrate and electrically connected to the wiring layer;
wherein the protruded structure includes a third protruded structure,
wherein the third protruded structure is interposed between the semiconductor chip and the electronic component, and
wherein the molding material molds the semiconductor chip along with the electronic component.

12. An electronic component package comprising:
a substrate including an insulating layer, a wiring layer including a connection pad, a protection layer disposed on the insulating layer, and at least one protruded structure disposed on the protection layer, wherein an opening is defined in the protection layer and the protruded structure is adjacent to the opening;
an electronic component disposed on the substrate and electrically connected to the connection pad; and
a molding material disposed on the substrate to mold the electronic component and including a resin and a filler,
wherein the opening exposes at least part of the connection pad and the insulating layer adjacent to the connection pad,
wherein the electronic component includes a region on the protruded structure and a region on the opening, and
wherein a gap between the region on the opening of the electronic component and the substrate is larger than an average particle diameter of the filler.

13. The electronic component package of claim 12, wherein:
the connection pad is embedded in the insulating layer and exposed to an upper surface facing the electronic component of the insulating layer.

14. The electronic component package of claim 12, wherein:
the gap between the region on the opening of the electronic component and the substrate is 46 μm or more.

15. The electronic component package of claim 12, wherein:
the filler includes silica (SiO₂).

16. The electronic component package of claim 12, wherein:
a thickness of the protruded structure is thicker than a thickness of the protection layer along a thickness direction.

17. The electronic component package of claim 12, wherein:
the molding material fills at least a part of a space between the substrate and the region on the opening of the electronic component.

18. The electronic component package of claim 12, wherein:
the region on the protruded structure of the electronic component is one of electrodes of the electronic component.

19. An electronic component package comprising:
a substrate including an insulating layer, a wiring layer including a first connection pad and a second connection pad, a protection layer disposed on the insulating layer, and at least one protruded structure disposed on the protection layer, wherein an opening exposing at least a portion of each of the first connection pad and the second connection pad is defined in the protection layer;
an electronic component disposed on the substrate and electrically connected to the first connection pad;
a semiconductor chip disposed on the substrate, wherein the semiconductor is spaced apart from the electronic component and electrically connected to the second connection pad;
a plurality of conductive bumps electrically connecting the semiconductor chip to the second connection pad;
an underfill resin interposed between the semiconductor chip and the substrate and covering the conductive bumps; and
a molding material disposed on the substrate to mold the electronic component and the semiconductor chip,
wherein the protruded structures include a first protruded structure, a second protruded structure, and a third protruded structure,
the first protruded structure and the second protruded structure support the electronic component, and
the third protruded structure blocks at least one side of the semiconductor chip on a plane.

20. The electronic component package of claim 19, wherein:
the first protruded structure and the second protruded structure include a same material.
